(19) United States
(12) Patent Application Publication
(10) Pub. No.: US 2009/0053019 A1
(43) Pub. Date: Feb. 26, 2009

(54) LOAD PORT AND LOAD PORT CONTROL METHOD

(75) Inventors: Shin Osaki, Kitakyushu-shi (JP); Mitsuaki Hagio, Kitakyushu-shi (JP); Takayuki Imanaka, Kitakyushu-shi (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: KABUSHIKI KAISHA YASKAWA DENKI, Kitakyushu-shi, Fukuoka (JP)

(21) Appl. No.: 11/908,036

(22) PCT Filed: Feb. 22, 2006
(86) PCT No.: PCT/JP2006/303143

§ 371 Date: Sep. 7, 2007

(30) Foreign Application Priority Data
Mar. 8, 2005 (JP) 2005-063224

(51) Int. Cl. H01L 21/677; B65G 49/07

(52) U.S. Cl. 414/222.01; 414/806

(57) ABSTRACT

A load port which has no limitation in a placing direction of a substrate storing container, is flexibly applicable in accordance with a mode of a device to which the load port is connected, and is compact, is provided. Furthermore, the load port having high operation efficiency is provided. The load port is provided with a stage (12) for placing the substrate storing container, and a transferring mechanism for transferring the stage. The load port for opening and closing a cover of the placed substance storing container is provided with a rotating mechanism for rotating the stage (12), and a lifting and lowering mechanism for lifting and lowering the stage.

### FIELD OF THE INVENTION

The present invention relates to a load port for opening and closing a cover of a substrate storing container in which semiconductor substrates are stored, more specifically to an inversion type load port capable of opening and closing the cover irrespective of a direction of the placed substrate storing container and the control method.

### TECHNICAL BACKGROUND

A conventional inversion type load port capable of opening and closing a cover of a FOUP (Front Opening Unified Pod) irrespective of the placing direction of the placed FOUP is shown in FIG. 4 (see, e.g., Patent Document 1).

In FIG. 4, the reference numeral 41 denotes a placing plate for placing a FOUP. 42 and 43 are rotary lifting and lowering means for rotating the placing plate 41. 44 denotes a stage configured to transfer the FOUP on a table 45 in the arrow direction D after receiving the FOUP from the placing plate 41. 47 is a load port door for opening and closing the cover of the FOUP. In FIG. 4, after placing the FOUP on the placing plate 41, the placing plate 41 is rotated with the rotary lifting and lowering means, so that the opening of the FOUP placed on the placing plate 41 faces to the load port door 47. When the opening of the FOUP faces to the load port door 47, the placing plate 41 is lowered with the rotary lifting and lowering means 42 and 43. As the placing plate 41 is lowered, a part of the FOUP comes into contact with the stage 44. Further lowering of the placing plate 41 causes detachment of the FOUP from the placing plate 41, resulting in complete placing of the FOUP on the stage 44. Thereafter, the stage 44 is moved on the table 45 in the arrow direction D and the FOUP is docked with the load port door 47 to open the FOUP door, whereby substrates stored in the FOUP will be delivered to semiconductor manufacturing equipment.

As explained above, according to a conventional load port, it is not required to provide a delivering means for delivering a FOUP from the placing plate 41 to the stage 44. The FOUP can be delivered to the stage 44 by lowering the placing plate 41.

Patent Document: JP2004-140011, A (see pages 4-8, FIG. 1)

### DISCLOSURE OF THE INVENTION

### Problems to be Solved by the Invention

In a conventional load port, a supporting portion 46 accommodating a control portion of the rotary lifting and lowering means 42 and 43 is large and protruded frontward with respect to the load port. Thus, there is a problem that a stocker, etc., which is to be connected at the load port front side, will be restricted in structure. There also was a problem that the supporting portion will be an obstacle at either the time of placing a load port or at the time of maintenance. In addition, since the placing plate 41 on which a FOUP is initially placed and the stage 44 are provided independently, at the time of delivering the FOUP from the placing plate 41 to the stage 44, it is required to position the stage 44 to a prescribed position. However, since the structure is not simple, there are costs and/or reliability problems.

The present invention was made in view of the aforementioned problems, and aims to provide a compact inversion type load port with no protruded supporting portion irrespective of the inversion type load port. It also aims to provide an inversion type load port high in operation efficiency.

### Means to Solve the Problems

In order to solve the aforementioned problems, the present invention is constituted as follows.

According to the invention as recited in claim 1, a load port comprises:

a stage for placing a substrate storing container;

a transferring mechanism for transferring the stage;

a rotating mechanism for rotating the stage; and

a lifting and lowering mechanism for lifting and lowering the stage,

wherein a cover of the placed substrate storing container is opened and closed.

According to the invention as recited in claim 2, a load port comprises:

a stage for placing a substrate storing container, the stage having at least a first stage and a second stage;

a transferring mechanism for transferring the stage;

a rotating mechanism for rotating both the first stage and the second stage;

a lifting and lowering mechanism fixed to the rotating mechanism, the lifting and lowering mechanism being configured to lift and lower only the first stage; and

a clamp for fixing the substrate storing container placed on the second stage, wherein a cover of the placed substrate storing container is opened and closed.

According to the invention as recited in claim 3, the first stage is provided with a clamp for fixing the substrate storing container.

According to the invention as recited in claim 4, the load port further comprises a position sensor for detecting that any one of the transferring mechanism, the rotating mechanism, the lifting and lowering mechanism, and the clamp has reached a prescribed position.

According to the invention as recited in claim 5, the load port further comprises a timer for monitoring a time lapse from initiation of an operation of any one of the transferring mechanism, the rotating mechanism, the lifting and lowering mechanism, and the clamp.

According to the invention as recited in claim 6, the stage is eccentrically rotated with the rotating mechanism.

According to the invention as recited in claim 7, the rotating mechanism is provided with a rotary cylinder and a belt-pulley mechanism.

According to the invention as recited in claim 8, an electric motor is employed in place of the rotary cylinder.

According to the invention as recited in claim 9, the lifting and lowering mechanism is an air cylinder.

According to the invention as recited in claim 10, a load port control method of controlling a load port comprising a stage for placing a substrate storing container and a transferring mechanism for transferring the stage, the load port being configured to open and close a cover of the placed substrate storing container, wherein the stage includes a first stage and a second stage, the load port further comprising a rotating mechanism for rotating both the first stage together and the second stage, a lifting and lowering mechanism for lifting and lowering only the first stage, the lifting and lowering mechanism being fixed to the rotating mechanism, and a clamp for fixing the substrate storing container placed on the second stage,

the method comprises:

a step of placing the substrate storing container on the stage;

a step of lowering the stage;

a step of performing a clamp operation of the clamp provided at the second stage;

a step of rotating the stage; and

a step of performing a docking operation of the stage.

According to the invention as recited in claim 11, a load port control method of controlling a load port comprising a stage for placing a substrate storing container and a transferring mechanism for transferring the stage, the load port being configured to open and close a cover of the placed substrate storing container, wherein the stage includes a first stage and a second stage, the load port further comprising a rotating mechanism for rotating both the first stage and the second stage, a lifting and lowering mechanism for lifting and lowering only the first stage, the lifting and lowering mechanism being fixed to the rotating mechanism, and a clamp for fixing the substrate storing container placed on the second stage,

the method comprises:

a step of placing the substrate storing container on the stage;

a step of performing a clamp operation of the clamp provided at the first stage;

a step of lowering the stage;

a step of rotating the stage; and

a step of performing a docking operation of the stage.

According to the invention as recited in claim 12, after an operation at any step meets a prescribed interlock condition, another step is executed.

According to the invention as recited in claim 13, the prescribed interlock condition is a detection signal output of a position detection sensor for detecting that the operation has reached a prescribed position.

According to the invention as recited in claim 14, the prescribed interlock condition is a prescribed time lapse counted by a timer.

### EFFECTS OF THE INVENTION

According to the invention as recited in claim 1 or claim 2, since the stage rotates, there is no limitation in a placing direction of the substrate storing container, and therefore the load port can be flexibly applied in accordance with a mode of a device to which the load port is connected. Furthermore, since the stage itself performs lifting, lowering, and rotating operations, it is compact.

Furthermore, according to the invention as recited in claims 3, 4, 5, 9, 10, 11, 12 and 13, since each load port axial operation can be performed simultaneously, the operation efficiency is high, which can improve the throughput.

### BRIEF DESCRIPTION OF THE DRAWINGS

FIG. 1 is a perspective view showing a load port according to a first embodiment of the present invention.

FIG. 2 is a side view showing a lifting and lowering operation of the load port according to the present invention.

FIG. 3 is an explanatory view showing a rotary lifting and lowering mechanism of the load port according to the present invention.

FIG. 4 is a perspective view showing a conventional load port.

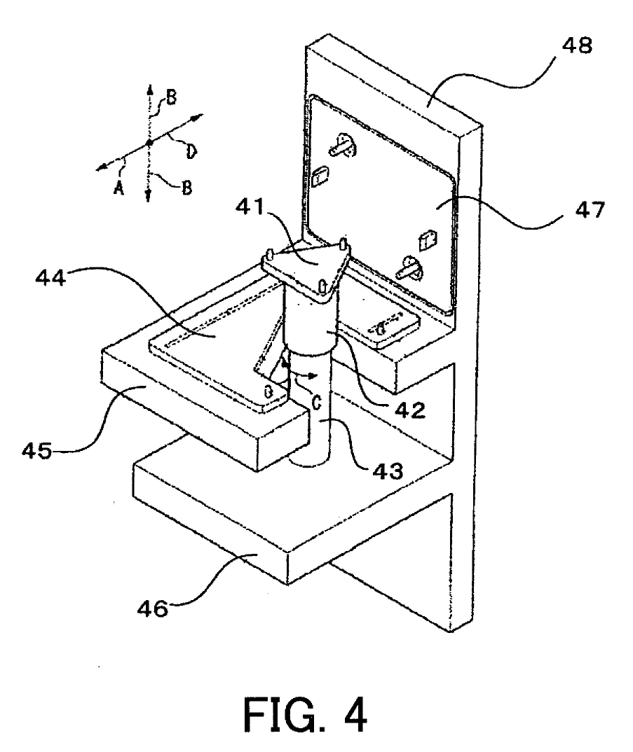

### BRIEF DESCRIPTION OF REFERENCE NUMERALS

11 Door
12 Stage
13 Clamp
15a, 15b Absorption means
16a, 16b Latch key
31 Rotary cylinder
32 Pulley
33 Belt
34 Pulley
35 Member
36 Lifting stage
37a, 37b, 37c Kinematic pin
38 Docking stage
39 Air cylinder

### BEST MODE FOR CARRYING OUT THE INVENTION

Hereinafter, embodiments of the present invention will be explained with reference to drawings.

### Embodiment 1

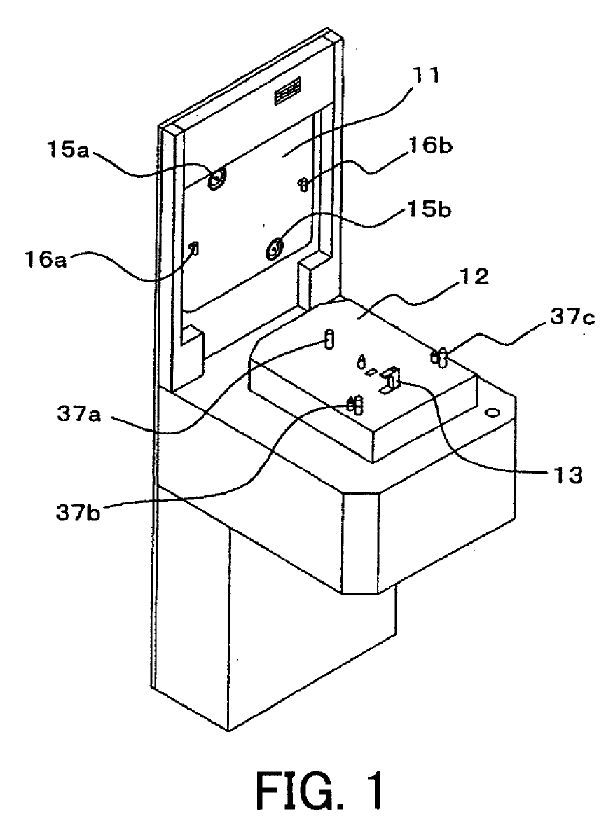

FIG. 1 is a perspective view of a load port according to the present invention. In FIG. 1, the reference numeral 12 denotes a stage for placing a substrate storing container such as, e.g., a FOUP. 13 denotes a clamp for fixing the placed substrate storing container. 15a and 15b are absorption means for absorbing the cover of the substrate storing container. 16a and 16b are latch keys for opening and closing a key of the cover of the substrate storing container. 11 is a load port door for opening and closing the cover of the substrate storing container placed on the stage 12.

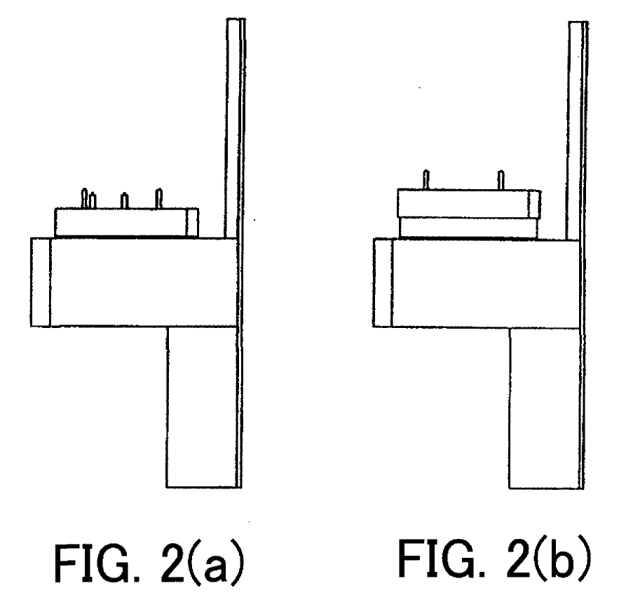

FIG. 2 is a side view of the load port of the present invention. The stage 12 of this load port is equipped with a lifting and lowering means (lift shaft) so as to lift and lower the stage 12. FIG. 2(a) shows the state in which the lift shaft is lowered, and FIG. 2(b) shows the state in which the lift shaft is lifted. Although not illustrated, the stage 12 is equipped with a rotary shaft for rotating the stage 12. The stage 12 includes a lifting stage 36 and a docking stage 38 therein, which will be described later.

The present invention is different from the aforementioned load port disclosed by Patent Document 1 in that the stage 12 itself is lifted/lowered and rotated and that a placing plate and a supporting portion accommodating a control portion for the rotary lifting and lowering means for the placing plate are eliminated.

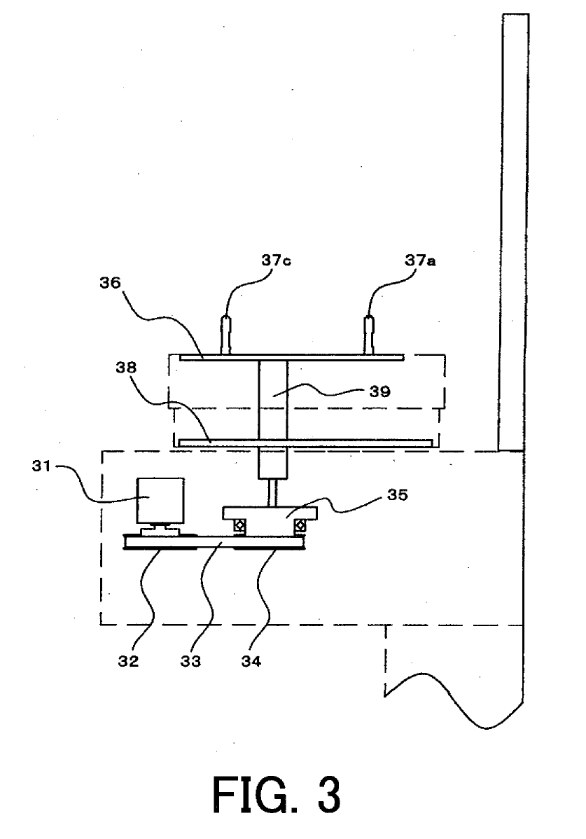

FIG. 3 is an explanatory view showing an internal mechanism for lifting/lowering and rotating the load port of the present invention. The broken line denotes a cover thereof. In FIG. 3, 36 denotes a first stage, which is a lifting stage in this embodiment. The lifting stage 36 is fixed to the main body side of the air cylinder 39, so that the lifting stage 36 is lifted and lowered in accordance with the driving of the air cylinder 39. 37 is a Kinematic pin fixed to the lifting stage 36. This Kinematic pin 37a and 37c is used to position the placed substrate storing container, which is the same as a conventional one. 31 denotes a rotary cylinder to be pneumatically rotated. On the other hand, the rotary cylinder 31 drives the belt-pulley mechanism constituted by a pulley 32, a belt 33 and a pulley 34. 35 is a member fixed to the pulley 34, and a shaft of the air cylinder 39 is fixed to the member 35. 38 is s second stage, which is a docking stage in this embodiment. The docking stage 38 is fixed to the member 35 via a frame (not illustrated). The rotary cylinder 31 is mounted on a linear guide (not illustrated), and the member 35 is also mounted on the linear guide via a bearing. Thus, the air cylinder 39, the member 35, the lifting stage 36 and the docking stage 38 are configured to integrally move in the right and left direction of this figure. Further mounted on the docking stage 38 are a clamp (not illustrated) and a normal disposition sensor (not illustrated). Accordingly, in a state in which the lifting stage 36 is lifted, the clamp and the normal disposition sensor will be located within the stage 12 and cannot be observed from the outside.

Next, the lifting/lowering and rotating operation of the stage will be explained. When the shaft is pushed out in accordance with the driving of the air cylinder 39, the main body of the air cylinder 39 is lifted up and the lifting stage 36 fixed to the air cylinder 39 is also lifted up. To the contrary, when the shaft is retreated in accordance with the driving of the air cylinder 39, the lifting stage 36 is lowered. In short, in accordance with the driving of the air cylinder 39, the lifting stage 36 is lifted/lowered.

On the other hand, when the rotary cylinder 31 is rotary driven, the belt-pulley mechanism constituted by the pulley 32, the belt 33 and the pulley 34 is driven, which in turn rotates the member 35 fixed to the pulley 34. In accordance with the rotation of the member 35, the lifting stage 36 fixed to the air cylinder 39 will be rotated. Here, the rotation center of the member 35 is provided in an offset manner with respect to the center of the stage 12, which rotates the stage 12 eccentrically. The reason of eccentrically rotating the stage 12 is to avoid mutual interference of substrate storing containers adjacently placed on load ports. In this embodiment, the revolution (rotation) area of a substrate storing container placed on the stage 12 is held within a diameter of 505 mm.

Although the lifting/lowering and rotating operations of the stage 12 were explained separately, the lifting/lowering and rotating operations can be performed simultaneously.

Next, the operation of the entire load port, especially the opening operation of the substrate storing container in a state in which the substrate storing container is placed with the cover not facing to the load port door 11 will be explained. The opening operation of the substrate storing container will be performed in the following steps, assuming that the state in which the stage 12 (lifting stage 36) is in a lifted state is an initial state.

(1) The substrate storing container is placed on the stage 12.
(2) The stage 12 (lifting stage 36) is lowered.
(3) The clamp clamps the substrate storing container (clamp operation).
(4) The stage 12 is rotated with the substrate storing container placed thereon, so that the opening of the substrate storing container faces the load port door 11 (rotation operation).
(5) The stage 12 moves in the rightward direction of this figure, whereby the cover of the substrate storing container is docked with the load port door 11 (docking operation)
(6) The absorption means 15a and 15b absorb the cover of the substrate storing container.
(7) The latch keys 16a and 16b rotate the key of the substrate storing container to release the lock of the door.

Subsequent operations are the same as those of a conventional load port, and therefore the explanation will be omitted. The above steps (4) and (5) can be performed simultaneously.

Here, in cases where the substrate storing container is placed with the cover facing the load port door, the operation of the aforementioned step (4) is not required. Furthermore, in cases where an operator manually executes step (1), the lifting of the stage 12 (lifting stage 36) as an initial state, step (2) will not be required. In other words, by choosing the aforementioned steps in accordance with the placing method of the substrate storing container, flexible operations can be performed, so that the load port of this embodiment can be handled like a conventional load port with no inversion function.

As explained above, in the load port of this embodiment, since the stage rotates, there is no restriction in a placing direction of the substrate storing container, which enables flexible operation in accordance with the mode of the apparatus to which the load port is connected. Furthermore, the stage is compact in size since the stage itself performs the lifting/lowering, rotating operations, resulting in a smaller footprint.

### Embodiment 2

Next, a load port according to a second embodiment of the present invention will be explained. In this load port of this embodiment, the clamp is provided at the lifting stage. The other structures other than the above are the same as those of the first embodiment, and therefore the detailed explanation will be omitted.

The opening operation of the substrate storing container will be performed in the following steps.

(1) The substrate storing container is placed on the stage 12.
(2) The clamp clamps the substrate storing container (clamp operation).
(3) The stage 12 (lifting stage 36) is lowered.
(4) The stage 12 is rotated with the substrate storing container placed thereon, so that the opening of the substrate storing container faces the load port door 11 (rotation operation).
(5) The stage 12 moves in the rightward direction of FIG. 3, whereby the cover of the substrate storing container is docked with the load port door 11 (docking operation)

Since the subsequent steps are the same as those of embodiment 1, the explanation will be omitted. The aforementioned steps (2) to (5) can be performed simultaneously. The operation of the steps (3) to (5) can be arbitrarily selected and performed simultaneously. However, if the docking operation can be completed in a shorter time than another operation, to avoid the interference of the substrate storing container with the load port main body, before completion of the docking operation at the step (5), all of the operations at the steps (3) and (4) should be completed.

As an example in which the aforementioned steps are performed simultaneously, a case in which only the rotation operation (step (4)) and the docking operation (step (5)) are performed simultaneously will be explained. Here, it is assumed that the docking operation will be completed in a shorter time than the rotation operation and a detection means for detecting that the stage has reached a prescribed rotational position is provided as an interlock.

Initially, after the completion of step (3), the controller of the load port outputs a rotational operation command to rotate the stage 12. Next, when the stage has reached the prescribed rotation position, the detecting means outputs a signal (interlock signal) to the controller. Then, the controller receives the outputted signal and outputs a docking command. Thereafter, the docking operation will be performed simultaneously with the rotational operation.

By initiating the docking operation during the rotational operation as mentioned above, the operation time can be shortened as compared with the case in which the rotational operation and the docking operation are performed separately, thereby improving the operation efficiency.

The detecting means can be a position sensor for detecting that the stage has reached a prescribed position. Alternatively, it can be configured such that a time from the initiation of each operation is monitored and when a certain time has passed it is considered that the stage has reached a prescribed position. In any event, any detection can be employed so long as the docking will be completed first during the rotational operation and a position where the substrate storing container does not interfere with the load port can be detected.

Furthermore, the simultaneous operations are not limited to the aforementioned rotational operation and the docking operation, but can be any combination of another axis. Furthermore, it is not limited to two simultaneous axial operations, but a plurality of axes can be operated simultaneously.

As mentioned above, in the load port of this embodiment, the clamp is provided at the list stage. Therefore, after clamping the substrate storing container, operations can be executed simultaneously until docking, resulting in improved efficient operation, which improves the throughput.

In the aforementioned two embodiments, the load port of the present invention employs an air cylinder as a driving means. However, an electric motor can be employed as a driving means.

Although a belt-pulley mechanism is employed as a mechanism for rotating the stage 12, a direct drive by a rotary cylinder can be employed in place of the mechanism.

What is claimed is:

1. A load port, comprising:
a stage for placing a substrate storing container;
a transferring mechanism for transferring the stage;
a rotating mechanism for rotating the stage; and
a lifting and lowering mechanism for lifting and lowering the stage,
wherein a cover of the placed substrate storing container is opened and dosed.

2. A load port, comprising:
a stage for placing a substrate storing container, the stage having at least a first stage and a second stage;
a transferring mechanism for transferring the stage;
a rotating mechanism for rotating both the first stage and the second stage;
a lifting and lowering mechanism fixed to the rotating mechanism, the lifting and lowering mechanism being configured to lift and lower only the first stage; and
a clamp for fixing the substrate storing container placed on the second stage,
wherein a cover of the placed substrate storing container is opened and closed.

3. The load port as recited in claim 2, wherein the first stage is provided with a clamp for fixing the substrate storing container.

4. The load port as recited in claim 2 or 3, further comprising a position sensor for detecting that any one of the transferring mechanism, the rotating mechanism, the lifting and lowering mechanism, and the clamp, has reached a prescribed position.

5. The load port as recited in claim 2 or 3, further comprising a timer for monitoring a time lapse from initiation of an operation of any one of the transferring mechanism, the rotating mechanism, the lifting and lowering mechanism, and the clamp.

6. The load port as recited in any one of claims 1 to 3, wherein the stage is eccentrically rotated with the rotating mechanism.

7. The load port as recited in claim 6, wherein the rotating mechanism is provided with a rotary cylinder and a belt-pulley mechanism.

8. The load port as recited in claim 7, wherein an electric motor is employed in place of the rotary cylinder.

9. The load port as recited in claim 8, wherein the lifting and lowering mechanism is an air cylinder.

10. A load port control method of controlling a load port comprising a stage for placing a substrate storing container and a transferring mechanism for transferring the stage, the load port being configured to open and close a cover of the placed substrate storing container, wherein the stage includes a first stage and a second stage, the load port further comprising a rotating mechanism for rotating both the first stage together and the second stage, a lifting and lowering mechanism for lifting and lowering only the first stage, the lifting and lowering mechanism being fixed to the rotating mechanism, and a clamp for fixing the substrate storing container placed on the second stage,
the method comprising:
a step of placing the substrate storing container on the stage;
a step of lowering the stage;
a step of performing a clamp operation of the clamp provided at the second stage;
a step of rotating the stage; and
a step of performing a docking operation of the stage.

11. A load port control method of controlling a load port comprising a stage for placing a substrate storing container and a transferring mechanism for transferring the stage, the load port being configured to open and close a cover of the placed substrate storing container, wherein the stage includes a first stage and a second stage, the load port further comprising a rotating mechanism for rotating both the first stage and the second stage, a lifting and lowering mechanism for lifting and lowering only the first stage, the lifting and lowering mechanism being fixed to the rotating mechanism, and a clamp for fixing the substrate storing container placed on the second stage,
the method comprising:
a step of placing the substrate storing container on the stage;
a step of performing a clamp operation of the clamp provided at the first stage;
a step of lowering the stage;
a step of rotating the stage; and
a step of performing a docking operation of the stage.

12. The load port control method as recited in claim 10 or 11, wherein after an operation at any step meets a prescribed interlock condition, another step is executed.

13. The load port control method as recited in claim 12, wherein the prescribed interlock condition is a detection signal output of a position detection sensor for detecting that the operation has reached a prescribed position.

14. The load port control method as recited in claim 12, wherein the prescribed interlock condition is a prescribed time lapse counted by a timer.
